(19) United States
(12) Patent Application Publication
(10) Pub. No.: US 2010/0071881 A1
(43) Pub. Date: Mar. 25, 2010

(54) COOLING SYSTEM FOR AIRCRAFT ELECTRIC OR ELECTRONIC DEVICES

(75) Inventors: Yann MURER, Saint-Jean (FR); Augustin ZELLER, Toulouse (FR)

Correspondence Address: OSLER, HOSKIN & HARCOURT LLP (AIRBUS), 1000 DE LA GAUCHETIERE STREET WEST, SUITE 2100, MONTREAL, QC, H3B-4W5, CA

(73) Assignee: AIRBUS OPERATIONS, Toulouse Cedex 9 (FR)

(21) Appl. No.: 12/540,505

(22) Filed: Aug. 13, 2009

(30) Foreign Application Priority Data
Aug. 21, 2008 (FR) 0855669
Aug. 21, 2008 (FR) 0855670

(51) Int. Cl. F28D 15/00; H05K 7/20

(52) U.S. Cl. 165/104.33; 361/699

(57) ABSTRACT

A cooling system for cooling the electrical or electronic equipment on board an aircraft is equipped with a main closed circuit. A pump circulates a heat transfer medium through the main closed circuit. A main heat exchanger is thermally coupled with the heat transfer medium. A secondary heat exchanger allows direct thermal coupling of the heat transfer medium to air on the outside of the aircraft. A bypass valve located upstream from the secondary heat exchanger allows to block, at least partially, the circulation of the heat transfer medium towards the secondary heat exchanger. A bypass duct connects the bypass valve to a point on the main closed cooling circuit downstream from the secondary heat exchanger to bypass, at least partially, the heat transfer medium towards the main heat exchanger as a function of a setting of the bypass valve.

### CROSS-REFERENCE

This application claims priority to French application FR 08 55669, filed on Aug. 21, 2008, and to French application FR 08 55670, filed on Aug. 21, 2008, the entirely of which is included by reference into this application.

### FIELD OF THE INVENTION

This invention related to a cooling system for cooling the electrical or electronic equipment on board an aircraft. The invention also relates to an aircraft equipped with such a system.

### BACKGROUND OF THE INVENTION

An aircraft, such as a modern commercial transport aircraft, has various electrical and electronic equipments intended for its good operation, in particular electronic equipment used in the avionic systems, and general electrical equipment. This equipment is usually contained in holds and cabinets located in various places in the structure of the aircraft. These holds and cabinets are usually equipped with cooling systems, in particular forced air cooling systems, that make it possible to control their inside temperature, in order to prevent the electrical and electronic equipment contained in them from overheating.

However, due (i) to the increase in power density of the new electrical and electronic equipment used in modern commercial aircraft or in those intended to equip the commercial aircraft under development, (ii) to the increase in the number of components of electrical and electronic equipment to be cooled, and (iii) to the fact that this equipment is more and more tightly consolidated, the electrical and electronic equipment of commercial aircraft releases more and more heat and the air temperature of the holds and cabinets in which it is consolidated tends to increase significantly. Conversely, the new electrical and electronic equipment developed for commercial aviation, and in particular the electronic equipment of avionic systems, requires more and more to be operated at well controlled temperatures.

Without an appropriate cooling system, the ambient temperature of the holds and cabinets in which is located the electrical or electronic equipment can increase above the maximum temperature at which this equipment can be operated. This can lead to the following results: malfunction of the equipment, a decrease in its useful life, breakdown or final damage. Such a situation is critical for the electrical and electronic equipment used in the operation of an aircraft, such as a commercial transportation airplane.

The forced air cooling systems used until now in commercial aviation do not make it possible to cool appropriately the electrical and electronic equipments of future commercial aircrafts, and adapting the types of known solutions, among which the increase in the quantity and flow of the forced air over the components to be cooled, has some disadvantages that make them unpractical: (i) low thermal efficiency, (ii) decrease in the space available on the aircraft, (iii) noise increase, (iv) increased energy consumption, and (v) risk of damage to the equipment cooled.

It was also considered to cool certain electrical equipment of a military aircraft with the help of a cooling system consisting of a closed circuit through which circulates a fluid heat transfer medium cooled in turn by a stand-alone cooling system. Such systems could offer better performance than the known forced air systems. The Aerospace Information Report titled “Liquid Cooling Systems,” issued by the Society for Automotive Engineers Inc. organization (SAE) on September 1985, as revised on October 1997 and October 2003 (hereinafter the “SAE Report”), contains a summary of certain systems using a closed circuit through which circulates a fluid heat transfer medium that can be used in military aircraft. However, since the constraints for the development of military aircraft are different from the constraints for the development of commercial aircraft, the systems described in the “SAE Report” are not optimal for commercial aircraft.

### SUMMARY OF THE INVENTION

In one embodiment of the invention, a cooling system for cooling an electrical or electronic equipment on board an aircraft is equipped with a main closed circuit comprising:
a pump to circulate a heat transfer medium through the main closed circuit;
a main heat exchanger thermally coupled with the heat transfer medium;
a secondary heat exchanger allowing a direct heat coupling of the heat transfer medium with the air on the outside of the aircraft;
a bypass valve located upstream from the secondary heat exchanger, allowing to block, at least partially, the circulation of the heat transfer medium towards the secondary heat exchanger; and
a bypass duct connecting the bypass valve to a point on the main closed cooling circuit downstream from the secondary heat exchanger to bypass at least partially the heat transfer medium towards the main heat exchanger as a function of a control setting of the bypass valve.

Such a system may contribute to the achievement of a relatively high energy efficiency ratio by using the outside ambient air to cool the heat transfer medium circulating through the main closed circuit. The system may contribute to the provision of appropriate cooling in case of malfunction of the main heat exchanger.

In one form of embodiment, the main closed cooling circuit is adapted to cool:
a first compartment containing avionic systems of the aircraft; and
a second compartment containing electrical systems of the aircraft;

In another form of embodiment, the first compartment and the second compartments are placed in series in the main closed cooling circuit.

Such a form of embodiment may contribute, among other things, to the achievement of a good energy efficiency ratio, for example when the operating temperature of the equipment from the first compartment is lower than the operating temperature of the equipment in the second compartment.

In another form of embodiment, the system contains a valve controller adapted to vary the setting of the bypass valve as a function of at least one operating condition of the aircraft.

In another form of embodiment, the valve controller is adapted to vary the setting of the bypass valve as a function of the outside temperature.

In another form of embodiment, the system contains a valve controller adapted to control the pump so that the heat transfer medium circulates through the main closed circuit at a flow that varies as a function of the heat released by the electrical or electronic equipment.

In another form of embodiment, the system comprises:
a second fluidically closed cooling circuit independent from the main closed circuit, the second closed cooling circuit comprising:
   at least one compressor adapted to circulate a liquid coolant through the second closed cooling circuit; and
   a heat exchanger adapted to cool the liquid coolant that circulates through the second closed cooling circuit by means of the outside ambient air;
the main heat exchanger of the main closed circuit is adapted to transmit the heat from the liquid coolant of the main closed circuit to the liquid coolant of the second closed cooling circuit, by evaporation of the liquid coolant that circulates through the second closed cooling circuit; and
the heat exchanger of the second closed cooling circuit makes possible the condensation of the liquid coolant circulating through the second closed cooling circuit.

In another form of embodiment, the main closed circuit is adapted to cool a third group of electrical or electronic equipment containing flight instruments from the aircraft's cockpit.

Another embodiment of the invention refers to an aircraft with a cooling system as described above.

### DESCRIPTION OF FIGURES

This invention is illustrated by non restrictive examples of the figures attached, where identical references show similar elements:

FIG. 1 is a schematic illustration of a first possible embodiment of the invention; and

FIG. 2 is a schematic illustration of a second possible embodiment of the invention.

### DETAILED DESCRIPTION OF AN EMBODIMENT OF THE INVENTION

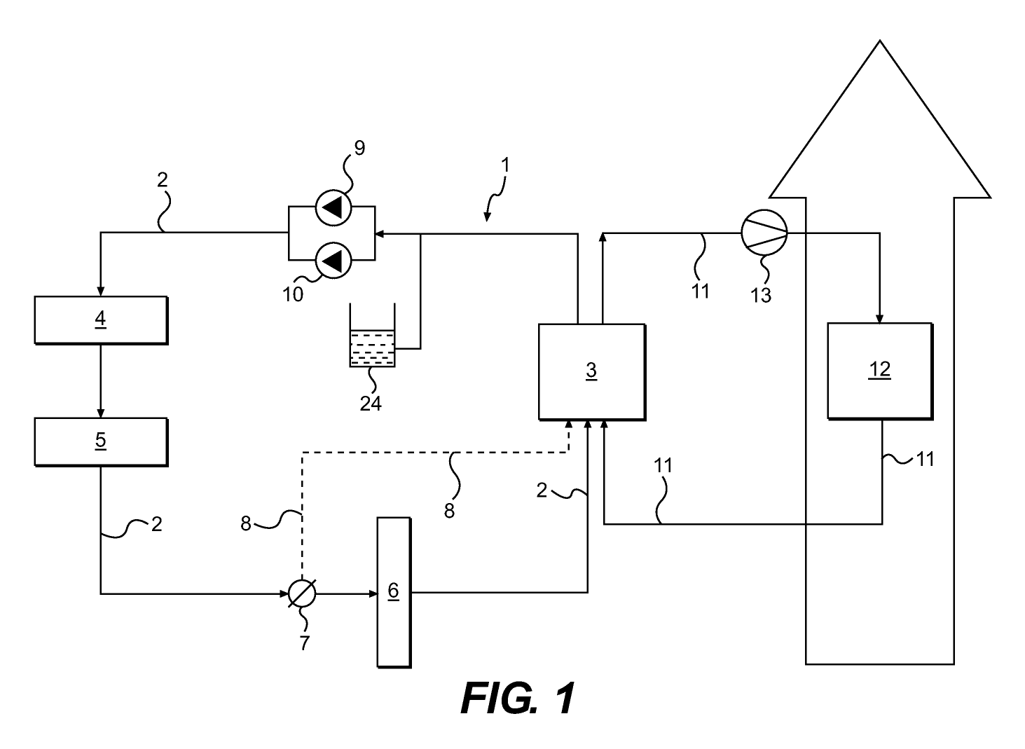

One possible embodiment of the invention is described below with reference to FIG. 1. This embodiment of the invention is given as an illustration and it should not limit in any way the scope of the invention. Other possible embodiments and possible variations thereof will be apparent to the average technician skilled in the art.

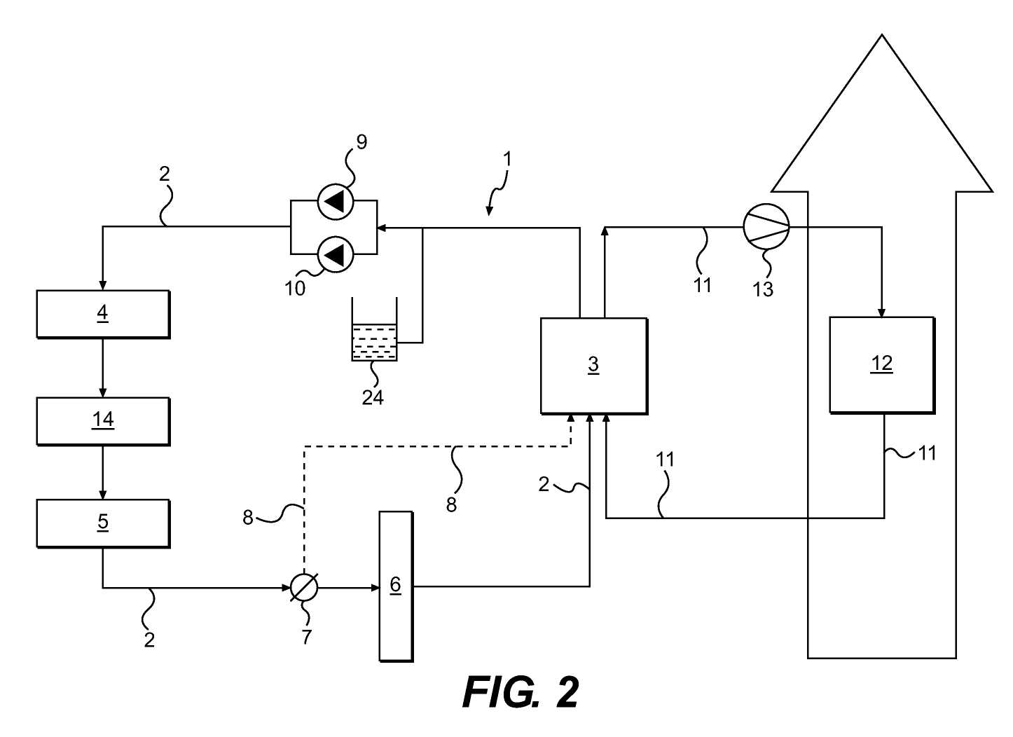

The cooling system for electrical or electronic equipment (1) comprises of a set of ducts forming a main closed circuit (2) through which circulates a heat transfer medium. The heat transfer medium can be any element or mixture of elements, in gaseous or fluid state, able to transfer heat. In the illustrative embodiments shown in FIGS. 1 and 2, the heat transfer medium is a fluid, for example a water based fluid, such as a water and glycol or water and methanol mixture. The ducts connect the various elements of the circuit. A main heat exchanger (3) thermally coupled with the fluid heat transfer medium is used to cool the latter to a temperature between approximately 10° C. and 15° C. The fluid heat transfer medium circulates in the direction indicated by the arrows on FIG. 1.

The system makes it possible to cool at least a first group of electrical or electronic equipment (4) and a second group of electrical or electronic equipment (5). In this illustrative embodiment of the invention, the first group of electrical or electronic equipment (4) comprises of electronic equipment of the avionic systems of a commercial transportation aircraft that can be, for example, mounted together depending on similar thermal needs in a first portion of the aircraft such as, for example, on a rack or in a compartment. In general, among them there is electronic equipment associated with aeronautics instrumentation and aircraft communications systems, among which there are, as an example, on-board computers, microprocessors and calculators, controllers, display units and screens, probes and antennas, etc. On the other hand, the second group of electrical or electronic equipment (5) comprises of electrical or electromechanical components generally associated with the operation of the aircraft, and in particular, also as an example, electric distribution centers, converters, rectifying installations, circuit breakers, actuators, electric pumps, etc. The equipment in the second group of electrical or electronic equipment (5) can be, for example, mounted together depending on similar thermal needs in a second portion of the aircraft, for example, on a rack, or in a compartment.

The electrical or electronic equipment of the two groups (4, 5) is cooled through a heat exchanger (not shown) which makes it possible to couple them thermally with the fluid heat transfer medium. The average technician skilled in the art knows several methods to couple a heat releasing equipment to a fluid heat transfer medium. In one embodiment of the invention, this heat exchanger may comprise of a network of coils located near the electrical or electronic equipment to be cooled or near a thermally conductive structure to which this equipment to be cooled is thermally connected and through which circulates the fluid heat transfer medium.

In the embodiment of the invention shown in FIG. 1, the first and the second group of electrical and electronic equipment (4, 5) are placed in series. In this embodiment of the invention where the first group of electrical or electronic equipment (4) comprises of the electronic equipment of the avionic system of the aircraft and the second group of electrical or electronic equipment (5) comprises of electrical and electromechanical components associated with the operation of the aircraft, such an arrangement in series allows optimum yield of the system, since the equipment in the first group (4) must be kept at a temperature lower than those in the second group (5). The temperature of the fluid heat transfer medium used to cool the equipment in the first group (4) may be between approximately 10° C. and 15° C. Once loaded with the heat released by the equipment in the first group (4), the fluid heat transfer medium can be transported directly towards the equipment in the second group (5), at a temperature of approximately 40° C., which is appropriate to make it possible to cool the equipment in this second group (5).

The embodiment of the invention shown in FIG. 1 also contains a secondary heat exchanger (6) that is an integral part of the main closed circuit (2). This secondary heat exchanger (6) is in the form of a skin heat exchanger that makes it possible to thermally couple the fluid heat transfer medium circulating through the main closed circuit (2) directly to the air on the outside of the aircraft. This embodiment of the invention makes it possible to cool the fluid heat transfer medium circulating through the main closed circuit (2), in a more effective way from the energetic point of view, and to achieve an appropriate cooling yield for the purpose of this invention, when the aircraft is at altitude or when the groups of electrical or electronic equipment (4, 5) are operated when the aircraft is on the ground in cold weather. Using such a secondary heat exchanger (6) makes it possible to save the energy required to cool the fluid heat transfer medium through the main heat exchanger (3).

When the aircraft is on the ground, a heat exchange between the air outside the aircraft and the fluid heat transfer medium circulating through the main closed circuit (2) may not be desired, since it might force a work overload on the main heat exchanger (3). A bypass valve (7) located before the secondary heat exchanger (6) makes it possible to divert, entirely or in part, the fluid heat transfer medium circulating through the main closed circuit (2) directly towards the main heat exchanger (3) by means of a bypass duct (8). The positioning of the valve and, therefore, the quantity of bypassed fluid heat transfer medium may vary as a function of the temperature outside the aircraft and of the temperature at which the groups of electrical or electronic equipment (4, 5) must be maintained. Therefore, the cooling system contains, preferably, a valve controller adapted to vary the setting of the bypass valve (7) as a function of at least one operation condition of the aircraft, such as, for example, the outside temperature that can be measured by a probe.

A thrust system, in this embodiment a pump (9) adapted to this type of function and whose specific choice of model will be obvious to the average technician skilled in the art, makes it possible to circulate the fluid heat transfer medium through the main closed circuit (2). This pump (9) is equipped with a control system (not shown) that makes it possible to adjust the flow as a function of the level of cooling desired for the electrical or electronic equipment (4, 5). The higher the capacity of the pump (9), the higher the flow of the fluid heat transfer medium through the main closed circuit (2). The flow control system of the pump is computerized. It is connected to one or several sensors (not shown) that measure the temperature of the fluid heat transfer medium at various key locations in the main closed circuit (2), for example immediately before and after the first group of electrical or electronic equipment (4), immediately before and after the second group of electrical or electronic equipment (5), and immediately before and after the main heat exchanger (3).

An auxiliary pump (10) is located in parallel with the pump (9) in order to take over and fulfill the same functions as the pump (9), if the latter stops operating appropriately.

A liquid coolant tank (24) makes it possible to compensate for the volume variations of the fluid heat transfer medium in the main closed circuit (2) due to the temperature changes to which it can be subjected, or to leaks.

Sensors (not shown) can be installed at various locations in the main closed circuit (2) to make it possible to measure the pressure and the velocity of the fluid heat transfer medium circulating through it at any moment when the cooling system (1) is in operation. This data could make it possible to detect, in particular, any leak in the main closed circuit (2) before the groups of electrical or electronic equipment (4, 5) are subjected to a temperature too high for their optimal operation.

The fluid heat transfer medium circulating through the main closed circuit (2) can be cooled at any moment by the main heat exchanger (3). In this embodiment of the invention, the main heat exchanger (3) is an evaporator that makes it possible to thermally couple the fluid heat transfer medium circulating through the main closed circuit (2) to a liquid coolant circulating through a main closed circuit (11).

A second heat exchanger (12) is also thermally coupled to the liquid coolant circulating through the second independent closed cooling circuit (11). This second heat exchanger (12) is a condenser cooled by a conventional forced air system well known to the average technician skilled in the art, for example a ram air in English (système à air dynamique, in French). The air used to cool the second heat exchanger (12) may come, in particular, from outside the aircraft, and be directed to the second heat exchanger (12) via an appropriate ventilation system.

The cooling cycle of the second independent closed cooling circuit (11) is basically as follows: the main heat exchanger (3) makes it possible to send the heat accumulated by the fluid heat transfer medium circulating through the main closed circuit (2) to the liquid coolant of the second independent closed cooling circuit (11), and then it is evaporated in gaseous state. This liquid coolant in gaseous state is transported to the second heat exchanger (12), which makes it possible to transfer the heat accumulated by the liquid coolant to the air used to cool this second heat exchanger (12). The cooled liquid coolant is then condensed to its liquid state and transported towards the main heat exchanger (3) in order to be heated again.

A thrust and compression system (13), such as a compressor, allows the liquid coolant in gaseous state to circulate from the main heat exchanger (3) towards the second main heat exchanger (12).

Another possible embodiment of the invention is described below with reference to FIG. 2. The system is similar to the one described above, with the exception that the system makes it possible to cool a first group of electrical or electronic equipment (4), a second group of electrical or electronic equipment (5), and a third group of electrical or electronic equipment (14), the groups being arranged in series.

In this embodiment of the invention, the first group of electrical or electronic equipment (4) comprises of electronic equipment of the avionic systems, the second group of electrical or electronic equipment (5) comprises of electrical or electromechanical components generally associated with the operation of the aircraft, and the third group of electrical or electronic equipment (14) comprises of flight instruments from the aircraft's cockpit.

The figures and their descriptions above illustrate the invention rather than limit it. Naturally, in order to meet the specific requirements, the average person skilled in the area of the invention will be able to apply modifications to the previous description.

The reference signs in the claims are not restrictive by any means. The verbs “to contain” and “to comprise” do not exclude the presence of other elements besides those listed in the claims. The word “a/an” preceding an element does not exclude the presence of several such elements.

1. A cooling system for cooling an electrical or electronic equipment on board an aircraft, the cooling system comprising a main closed circuit, the main closed circuit comprising:
a pump to circulate a heat transfer medium through the main closed circuit;
a main heat exchanger thermally coupled with the heat transfer medium;
a secondary heat exchanger allowing direct thermal coupling of the heat transfer medium to air on the outside of the aircraft;
a bypass valve located upstream from the secondary heat exchanger, allowing to block, at least partially, the circulation of the heat transfer medium towards the secondary heat exchanger; and
a bypass duct connecting the bypass valve to a point on the main closed circuit downstream from the secondary heat exchanger to allow the heat transfer medium to bypass, at least partially, towards the main heat exchanger as a function of a control setting of the bypass valve.

2. A cooling system according to claim 1, wherein the main closed circuit is adapted to cool:
a first compartment containing avionic systems of the aircraft; and
a second compartment containing electrical systems of the aircraft.

3. A cooling system according to claim 2, wherein the first compartment and the second compartment are placed in series in the main closed circuit.

4. A cooling system according to claim 1, further comprising a valve controller adapted to vary the setting of the bypass valve as a function of at least one operating condition of the aircraft.

5. A cooling system according to claim 4, wherein the valve controller is adapted to adjust the setting of the bypass valve as a function of the outside temperature.

6. A cooling system according to claim 1, further comprising a pump controller adapted to control the pump so that the heat transfer medium circulates through the main closed circuit at a flow that varies as a function of the heat released by the electrical or electronic equipment.

7. A cooling system according to claim 1, further comprising:
a second closed cooling circuit fluidically independent from the main closed circuit, the second closed cooling circuit comprising:
at least one compressor adapted to circulate a liquid coolant through the second closed cooling circuit; and
a heat exchanger adapted to cool the liquid coolant that circulates through the second closed cooling circuit by means of the outside ambient air;
the main heat exchanger of the main closed circuit is adapted to transfer the heat of the liquid coolant of the main closed circuit to the liquid coolant of the second closed cooling circuit by evaporation of the liquid coolant that circulates through the second closed cooling circuit; and
the heat exchanger of the second closed cooling system allows condensation of the liquid coolant circulating through the second closed cooling circuit.

8. A cooling system according to claim 1, wherein the main closed circuit is adapted to cool:
a third group of electrical or electronic equipment comprising flight instruments from the aircraft's cockpit.

9. An aircraft containing a cooling system for cooling the electrical or electronic equipment on board an aircraft, the cooling system containing a main closed circuit comprising:
a pump to circulate a heat transfer medium through the main closed circuit;
a main heat exchanger thermally coupled with the heat transfer medium;
a secondary heat exchanger allowing direct thermal coupling of the heat transfer medium with air on the outside of the aircraft;
a bypass valve located upstream from the secondary heat exchanger, allowing to block, at least partially, the circulation of the heat transfer medium towards the secondary heat exchanger; and
a bypass duct connecting the bypass valve to a point on the main closed circuit downstream from the secondary heat exchanger to allow the heat transfer medium to bypass at least partially towards the main heat exchanger as a function of a control setting of the bypass valve.

10. An aircraft containing a cooling system according to claim 9, wherein the main closed circuit is adapted to cool:
a first compartment containing avionic systems of the aircraft; and
a second compartment containing electrical systems of the aircraft.

11. An aircraft containing a cooling system according to claim 10, wherein the first compartment and the second compartment are placed in series in the main closed circuit.

12. An aircraft containing a cooling system according to claim 9, further comprising a valve controller adapted to vary the setting of the bypass valve as a function of at least one operating condition of the aircraft.

13. An aircraft containing a cooling system according to claim 12, wherein the valve controller is adapted to adjust the setting of the bypass valve as a function of outside temperature.

14. An aircraft containing a cooling system according to claim 9, further comprising a pump controller adapted to control the pump so that the heat transfer medium circulates through the main closed circuit at a flow that varies as a function of the heat released by the electrical or electronic equipment.

15. An aircraft containing a cooling system according to claim 9, further comprising:
a second closed cooling circuit fluidically independent from the main closed circuit, the second closed cooling circuit comprising:
at least one compressor adapted to circulate a liquid coolant through the second closed cooling circuit; and
a heat exchanger adapted to cool the liquid coolant that circulates through the second closed cooling circuit by means of outside ambient air;
the main heat exchanger of the main closed circuit is adapted to transfer the heat from the liquid coolant of the main closed circuit to the liquid coolant of the second closed cooling circuit, by evaporation of the liquid coolant that circulates through the second closed cooling circuit; and
the heat exchanger of the second closed cooling circuit allows condensation of the liquid coolant circulating through the second closed cooling circuit.

16. An aircraft containing a cooling system according to claim 9, wherein the main closed circuit is adapted to cool:
a third group or electrical or electronic equipment comprising flight instruments from the aircraft's cockpit.
